(19) United States
(12) Patent Application Publication
(10) Pub. No.: US 2024/0242963 A1
(43) Pub. Date: Jul. 18, 2024

(54) EPITAXIAL NITRIDE FERROELECTRONICS

(71) Applicant: The Regents of the University of Michigan, Ann Arbor, MI (US)

(72) Inventors: Zetian Mi, Ann Arbor, MI (US); Ping Wang, Ann Arbor, MI (US); Ding Wang, Ann Arbor, MI (US)

(21) Appl. No.: 18/559,490

(22) PCT Filed: May 9, 2022
(86) PCT No.: PCT/US2022/028365

§ 371 Date: Nov. 7, 2023

Related U.S. Application Data
(60) Provisional application No. 63/185,669, filed on May 7, 2021.

(51) Int. Cl. H01L 21/02; C30B 23/02; C30B 25/02; C30B 29/40; H01L 31/0735; H10B 51/30; H10B 53/30; H10B 63/00

(52) U.S. Cl. CPC H01L 21/02175; C30B 23/02; C30B 25/02; C30B 29/403; C30B 29/406; H01L 21/02266; H01L 21/02271; H01L 21/02337; H01L 21/0234; H01L 21/0242; H01L 21/0254; H01L 31/0735; H10B 51/30; H10B 53/30; H10B 63/00

(57) ABSTRACT

A method of fabricating a heterostructure includes providing a substrate, and implementing a non-sputtered, epitaxial growth procedure at a growth temperature to form a wurtzite structure supported by the substrate. The wurtzite structure includes an alloy of a III-nitride material. The non-sputtered, epitaxial growth procedure is configured to incorporate a group IIIB element into the alloy of the III-nitride material. The growth temperature is at a level such that the wurtzite structure exhibits a breakdown field strength greater than a ferroelectric coercive field strength of the wurtzite structure.

### CROSS-REFERENCE TO RELATED APPLICATION

This application claims the benefit of U.S. provisional application entitled “Epitaxial Nitride Ferroelectronics,” filed May 7, 2021, and assigned Ser. No. 63/185,669, the entire disclosure of which is hereby expressly incorporated by reference.

### STATEMENT REGARDING FEDERALLY SPONSORED RESEARCH OR DEVELOPMENT

This invention was made with government support under Contract No. N00014-19-1-2225 awarded by the U.S. Office of Naval Research. The government has certain rights in the invention.

### BACKGROUND OF THE DISCLOSURE

### Field of the Disclosure

The disclosure relates generally to ferroelectric Group III-nitride materials.

### Brief Description of Related Technology

The ability to control and tune electrical polarization of semiconductor materials has been investigated to enable the design and development of many types of devices, including, for instance, microelectronic memory devices for neuromorphic computing and artificial intelligence, reconfigurable filters for mobile communications, micro/nanoelectromechanical systems, and tunable two-dimensional electron/hole gas (2DEG/2DHG) heterojunctions. Wurtzite III-nitride semiconductors, e.g., AlN, GaN, InN, and their alloys, possess a strong polarization effect along the c-axis, including spontaneous and piezoelectric polarization. The polarization direction of conventional III-nitrides, however, cannot be electrically switched without causing dielectric breakdown.

Recent theoretical studies suggested that ferroelectric switching of III-nitride semiconductors could be potentially achieved through the incorporation of other noble metal elements and/or strain engineering. For example, the incorporation of Sc into AlN induces distortion of the wurtzite crystal structure, i.e., a reduction in the c/a ratio accompanied by an increase in the internal u parameter. The resulting tendency for transformation to a planar hexagonal structure leads to crystal structure destabilization and an enhanced piezoelectric response. Consequently, the electric field for ferroelectric polarization switching can be potentially reduced below its dielectric breakdown limit of wurtzite ScₓAl₁₋ₓN.

The synthesis and characterization of ScₓAl₁₋ₓN has been studied. Some studies on ScₓAl₁₋ₓN have largely focused on sputter deposition, and the ferroelectric switching of the resulting materials has been investigated. However, controlled synthesis of ScₓAl₁₋ₓN using molecular beam epitaxy (MBE) or metal-organic chemical vapor deposition (MOCVD) is also of interest. The epitaxial growth provides significantly improved material quality and enables seamless integration with III-N device technology. Pure wurtzite phase ScₓAl₁₋ₓN with Sc content up to 0.4 has been achieved using MBE. Further studies have confirmed that the energy bandgap decreases linearly with increasing Sc composition, in good agreement with theory. Other studies revealed that ScₓAl₁₋ₓN is optically active but is dominated by oxygen-defect related emission. To date, however, there has been no report on ferroelectric switching in ScₓAl₁₋ₓN grown by MBE or MOCVD.

### SUMMARY OF THE DISCLOSURE

In accordance with one aspect of the disclosure, a method of fabricating a heterostructure includes providing a substrate, and implementing a non-sputtered, epitaxial growth procedure at a growth temperature to form a wurtzite structure supported by the substrate, the wurtzite structure including an alloy of a III-nitride material, the non-sputtered, epitaxial growth procedure being configured to incorporate a group IIIB element into the alloy of the III-nitride material. The growth temperature is at a level such that the wurtzite structure exhibits a breakdown field strength greater than a ferroelectric coercive field strength of the wurtzite structure.

In accordance with another aspect of the disclosure, a method of fabricating a heterostructure includes providing a substrate, and implementing a non-sputtered, epitaxial growth procedure at a growth temperature to form a wurtzite structure supported by the substrate, the wurtzite structure including an alloy of a III-nitride material, the non-sputtered, epitaxial growth procedure being configured to incorporate a Group IIIB element into the alloy of the III-nitride material. The growth temperature is about 650 degrees Celsius or less.

In accordance with yet another aspect of the disclosure, a device includes a substrate and a heterostructure supported by the substrate. The heterostructure includes a monocrystalline layer of an alloy of a III-nitride material. The alloy includes a Group IIIB element.

In accordance with still another aspect of the disclosure, a device includes a substrate and a heterostructure supported by the substrate. The heterostructure includes a semiconductor layer supported by the substrate, and a ferroelectric III-nitride alloy layer supported by the semiconductor layer. The ferroelectric III-nitride alloy layer includes a Group IIIB element.

In connection with any one of the aforementioned aspects, the devices and/or methods described herein may alternatively or additionally include or involve any combination of one or more of the following aspects or features. The level of the growth temperature is at about 650 degrees Celsius or less. The method further includes forming a semiconductor layer supported by the substrate before implementing the non-sputtered, epitaxial growth procedure such that the wurtzite structure is formed on the semiconductor layer. Forming the semiconductor layer includes forming a III-nitride layer. The III-nitride layer is nitrogen-polar such that the wurtzite structure is nitrogen-polar. The semiconductor layer includes gallium nitride (GaN). Forming the semiconductor layer includes growing the semiconductor layer in an epitaxial growth chamber in which the non-sputtered, epitaxial growth procedure for the wurtzite structure is implemented such that the substrate is not removed from the epitaxial growth chamber between forming the semiconductor layer and implementing the non-sputtered, epitaxial growth procedure. The III-nitride layer is configured to promote growth of a metal-polar region, a nitrogen-polar region, or both metal- and nitrogen-polar regions when implementing the non-sputtered, epitaxial growth procedure. The method further includes forming a semiconductor layer after implementing the non-sputtered, epitaxial growth procedure such that the semiconductor layer is in contact with the wurtzite structure. Forming the semiconductor layer includes growing the semiconductor layer in an epitaxial growth chamber in which the non-sputtered, epitaxial growth procedure for the wurtzite structure is implemented such that the substrate is not removed from the epitaxial growth chamber between implementing the non-sputtered, epitaxial growth procedure and forming the semiconductor layer. The group IIIB element is scandium. The III-nitride material is aluminum nitride (AlN). The substrate includes sapphire. The substrate includes off-cut sapphire. The method further includes annealing the wurtzite structure at a temperature higher than the growth temperature. Annealing the wurtzite structure is implemented in a chamber in which the non-sputtered, epitaxial growth procedure is implemented. The method further includes forming a semiconductor layer supported by the substrate before implementing the non-sputtered, epitaxial growth procedure such that the wurtzite structure is formed on the semiconductor layer. Forming the semiconductor layer includes forming a III-nitride layer. The III-nitride layer is nitrogen-polar such that the wurtzite structure is nitrogen-polar. Forming the semiconductor layer includes growing the semiconductor layer in an epitaxial growth chamber in which the non-sputtered, epitaxial growth procedure for the wurtzite structure is implemented such that the substrate is not removed from the epitaxial growth chamber between forming the semiconductor layer and implementing the non-sputtered, epitaxial growth procedure. The method further includes forming a semiconductor layer after implementing the non-sputtered, epitaxial growth procedure such that the semiconductor layer is in contact with the wurtzite structure. Forming the semiconductor layer includes growing the semiconductor layer in an epitaxial growth chamber in which the epitaxial growth procedure for the wurtzite structure is implemented such that the substrate is not removed from the epitaxial growth chamber between implementing the epitaxial growth procedure and forming the semiconductor layer. The monocrystalline layer exhibits a breakdown field strength greater than a ferroelectric coercive field strength of the monocrystalline layer. The device further includes a semiconductor layer disposed between the substrate and the heterostructure. The semiconductor layer includes a further III-nitride material. The semiconductor layer is in contact with the heterostructure. The device further includes a metal layer disposed between the substrate and the heterostructure. The metal layer is in contact with the heterostructure. The ferroelectric III-nitride alloy layer is in contact with the semiconductor layer to establish a heterointerface. The ferroelectric III-nitride alloy layer is monocrystalline. The ferroelectric III-nitride alloy layer has a wurtzite structure. The semiconductor layer includes Si-doped GaN. The semiconductor layer is in contact with the substrate. The ferroelectric III-nitride alloy layer includes ScAlN. The semiconductor layer includes a III-nitride semiconductor. The semiconductor layer is nitrogen-polar. The ferroelectric III-nitride alloy layer is nitrogen-polar.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts an atomic force microscope (AFM) image of an epitaxially grown ScₓAl₁₋ₓN layer that exhibits ferroelectric characteristics in accordance with one example, along with a graphical plot of polarization-electric field (P-E) loops for ferroelectric layer examples having a range of scandium contents.

FIG. 2 depicts a graphical plot of current density as a function of electric field for a number of epitaxially grown ScₓAl₁₋ₓN layers in accordance with several examples, along with a graphical plots of the coercive field, breakdown field, and remnant polarization for varying levels of scandium content in epitaxially grown ScₓAl₁₋ₓN layers in accordance with several examples.

FIG. 3 depicts a graphical plot of polarization after positive and negative poling for an epitaxially grown ScₓAl₁₋ₓN layer in accordance with one example, as well as graphical plots of transient current and voltage profiles during positive-up and negative-down (PUND) measurements of an epitaxially grown ScₓAl₁₋ₓN layer in accordance with one example.

FIG. 4 depicts a graphical plot of remnant polarization during endurance testing of an epitaxially grown ScₓAl₁₋ₓN layer in accordance with one example, as well as a graphical plot of current density as a function of electric field for an epitaxially grown ScₓAl₁₋ₓN layer after a varying number of switching cycles in accordance with one example.

FIG. 5 is a graphical plot of the leakage current as a function of applied voltage for an epitaxially grown ScₓAl₁₋ₓN layer in accordance with one example.

FIG. 6 is a flow diagram of a method of fabricating a heterostructure having an epitaxially grown ferroelectric wurtzite structure in accordance with one example.

FIGS. 7A and 7B depict cross-sectional, schematic views of ferroelectric field effect transistor (FeFET) memory cells with a single-crystal, or monocrystalline, layer of an alloy of a III-nitride material (e.g., ScₓAl₁₋ₓN) between a gate electrode and a source-drain conduction region to provide a reversible electrical state in accordance with two examples.

FIG. 8 is a cross-sectional, schematic view of a ferroelectric-transistor random-access memory cell with a metal-ScₓAl₁₋ₓN-metal capacitor and a silicon or GaN based write-read transistor in accordance with one example.

FIGS. 9A and 9B are cross-sectional, schematic views of ferroelectric tunnel junction (FTJ) memory devices with a monocrystalline layer of an alloy of a III-nitride material (e.g., ScₓAl₁₋ₓN) in accordance with two examples.

FIGS. 10A and 10B are cross-sectional, schematic views of metal-polar and N-polar ferroelectric high electron mobility transistor (Fe-HEMT) devices, respectively, each having a monocrystalline layer of an alloy of a III-nitride material (e.g., ScₓAl₁₋ₓN) in accordance with two examples.

FIGS. 11A and 11B are cross-sectional, schematic views of a reconfigurable Fe-HEMT device having a monocrystalline layer of an alloy of a III-nitride material (e.g., ScₓAl₁₋ₓN) in accordance with one example, in which the polarization direction, indicated by green arrows, of a ferroelectric layer under a gate can be reconfigured by applying an electric field beyond the coercive field.

FIG. 12 is a cross-sectional, schematic view of a ferroelectric photovoltaic device with a monocrystalline layer of an alloy of a III-nitride material (e.g., ScₓAl₁₋ₓN) as a photon absorption layer in accordance with one example.

FIGS. 13A and 13B are cross-sectional, schematic views of ferroelectric photovoltaic devices, each having a monocrystalline layer of an alloy of a III-nitride material (e.g., ScₓAl₁₋ₓN) to provide one or more ferroelectric regions, and further having a monocrystalline layer of a III-nitride material as a photon absorption layer in accordance with two examples.

FIG. 14 is a cross-sectional, schematic view of a lateral homojunction device with a monocrystalline layer of an alloy of a III-nitride material (e.g., ScₓAl₁₋ₓN) to provide one or more ferroelectric regions in accordance with one example.

FIG. 15 depicts AFM and SEM images of a ferroelectric, N-polar ScAlN epilayer of a heterostructure in accordance with one example, along with graphical plots of (0002) plane XRD 2θ-ω scan data and (1012) plane XRD p scans of the heterostructure layers and underlying sapphire substrate, stereographic projections of XRD pole figures for the {2024} planes of the sapphire, {1012} planes of GaN, and {1012} planes of Sc_{0.21}Al_{0.79}N, showing exactly aligned single-crystalline wurtzite phase between GaN and Sc_{0.21}Al_{0.79}N.

FIG. 16 depicts graphical plots of ferroelectric behavior of an N-polar ScAlN layer in accordance with one example, including extracted J-E and P-E loops from a triangular waveform PUND measurement, a butterfly shaped C-V loop and the corresponding conductance (G) recorded on a device with a top electrode diameter of 50 m at 1 MHz (AC=100 mV), transient current in a PUND measurement using square pulses with pulse width and delay both equal to 0.02 ms, and an electric field of 4.8 MV/cm, and electric field dependent PUND measurements based on the pulse trains, showing saturated remnant polarization in both branches.

FIG. 17 depicts graphical plots of reliability measurements of ferroelectric N-polar ScAlN epilayers in multiple examples, including coercive field and remnant polarization measurements in 10 randomly distributed devices, retention testing for ferroelectric N-polar Sc_{0.21}Al_{0.79}N, showing a high stability of remnant polarization after electrical switching, endurance testing for ferroelectric N-polar Sc_{0.21}Al_{0.79}N, showing large and programmable remnant polarization up to 5×10⁵ electrical switching cycles, and variation of the coercive field after selected switching cycles, showing stability in the measured 10⁵ switching cycles, in which square pulse sequences with a voltage of ±48 V and a pulse width of 0.02 ms were executed in the retention and endurance testing.

FIG. 18 is a cross-sectional, schematic view of a device with a heterostructure that includes an N-polar alloy of a III-nitride material (e.g., ScₓAl₁₋ₓN) in accordance with one example.

FIG. 19 is a perspective, schematic view of a ferroelectric device with a layer of an alloy of a III-nitride material (e.g., ScₓAl₁₋ₓN) having regions of alternating polarity (N-polar and metal-polar) in accordance with one example.

The embodiments of the disclosed devices and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Methods for growth of epitaxial (e.g., fully epitaxial) ferroelectric alloys of III-nitride materials are described. The disclosed methods are configured to incorporate scandium (Sc) or other group IIIB elements into the wurtzite crystal structure of the III-nitride material.

Molecular beam epitaxy (MBE), metal-organic chemical vapor deposition (MOCVD), hydride vapor phase epitaxy (HVPE), pulsed laser deposition (PLD), and other non-sputtered epitaxial growth procedures may be used to realize the ferroelectric III-nitride alloys. The disclosed methods may or may not include implementation of a post-growth annealing procedure. Devices and structures including such materials are also described. For instance, various heterostructures and ferroelectronic devices with one or more ferroelectric III-nitride layers are described.

The disclosed devices and structures exhibit ferroelectric switching in one or more single-crystal, or monocrystalline, layers of an alloy of a III-nitride material, e.g., in ScₓAl₁₋ₓN films grown by molecular beam epitaxy (MBE). In some cases, the layers are grown on GaN templates or other III-nitride semiconductor layers. The ferroelectric properties of several examples of the ScₓAl₁₋ₓN films with varying Sc contents (e.g., with the Sc content, x, falling in a range from about 0.14 to about 0.36) are presented via polarization and current density over electric field (P-E and J-E, respectively) measurements. The polarization retention time and fatigue behavior of the examples are also presented. Ferroelectricity is exhibited in all of the examples of ScₓAl₁₋ₓN films. A coercive field of about 4.2 MV/cm was measured for Sc_{0.20}Al_{0.30}N at 10 kHz with a remnant polarization of about 135 μC/cm². Further testing revealed no obvious fatigue behavior after up to 3×10⁵ switching cycles. The disclosed methods and devices show the feasibility to control the electrical polarization of III-V semiconductors grown by MBE and other non-sputtered epitaxial growth procedures (e.g., MOCVD, HVPE, and PLD). The use of epitaxial growth procedures enables thickness scaling (e.g., into the nanometer regime). Epitaxial growth may be useful in fabricating a broad range of applications in electronic, photonic, optoelectronic, and ferroelectric devices.

In some examples, ScₓAl₁₋ₓN films were grown using a Veeco GENXpolar MBE system equipped with a radio-frequency (RF) plasma source. In these examples, a Si-doped GaN layer was first grown on GaN/sapphire template, which may be used as a bottom contact layer. Subsequently, a ScₓAl₁₋ₓN layer was grown. The layer may have a thickness of about 100 nanometers (nm), but the thickness may vary. The Sc content may be varied by tuning the Sc/Al flux ratio, which may be further confirmed by energy dispersive x-ray spectroscopy (EDS). Electrical properties of these examples were analyzed by a Radiant Precision Multiferroic II Ferroelectric Test System. Ferroelectric characterization of these examples was performed on parallel plate capacitors with 100-nm-thick Pt circular top electrodes structured by lift-off and an indium solder dot placed on the n-GaN as the bottom electrode. The diameters of the top electrodes were varied in a range of 20-50 μm. P-E and J-E hysteresis loops of these examples were measured with a triangular voltage. Standard positive-up and negative-down (PUND) measurements with a pulse width of 10 μs, and an inter-pulse delay of 1 ms, were used to detect the ferroelectricity loss in fatigue testing of the examples.

Although described in connection with examples of epitaxially grown ScₓAl₁₋ₓN layers, the disclosed methods and devices may be applied to a wide variety of III-nitride alloys. The disclosed methods and devices may thus include or involve the incorporation of scandium into other III-nitride wurtzite structures. For instance, the disclosed methods and devices may include or involve one or more epitaxially grown ScₓAl_{y}Ga_{1-x-y}N layers, ScₓGa₁₋ₓN layers, or ScₓIn₁₋ₓN layers. The configuration, construction, fabrication, and other characteristics of the heterostructures may also vary from the examples described. For instance, the heterostructures may include any number of epitaxially grown layers of ferroelectric and non-ferroelectric nature. The disclosed methods and devices are not limited to III-nitride alloys including scandium. For instance, the III-nitride alloys may include additional or alternative group IIIB elements, such as yttrium (Y) and lanthanum (La).

Although the disclosed methods are described in connection with MBE growth procedures, additional or alternative non-sputtered epitaxial growth procedures may be used. For instance, metal-organic chemical vapor deposition (MOCVD), hydride vapor phase epitaxy (HVPE), atomic layer deposition (ALD), and atomic layer epitaxy (ALE) growth procedures may be used. Still other procedures may be used, including, for instance, pulsed laser deposition procedures.

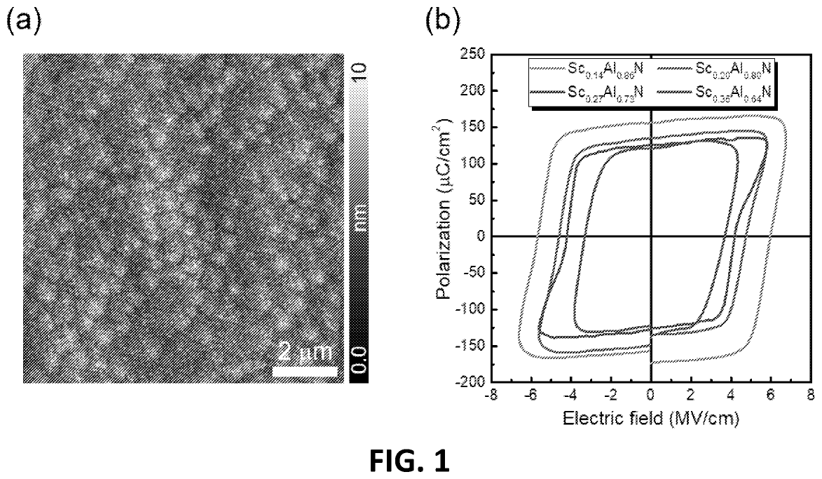

Part A of FIG. 1 depicts 10×10 μm² atomic force microscope (AFM) image of an example of a Sc_{0.20}Al_{0.80}N film grown in accordance with one example of the disclosed methods. The corresponding root-mean-square (RMS) roughness acquired from a 10×10 μm² scan area is about 1.1 nm. Other examples described herein exhibit similar surface morphology.

Part B of FIG. 1 depicts polarization-electric field (P-E) loops exhibited by the example. The P-E loops were measured at 40 kHz for ferroelectric ScₓAl₁₋ₓN with varying Sc contents. In these examples, the Sc content, x, varied from about 0.14 to about 0.36.

Further details regarding the example are provided below.

The disclosed methods were used to grow a number of wurtzite-phase ScₓAl₁₋ₓN/GaN heterostructures. The ScₓAl₁₋ₓN layer of the heterostructures exhibited ferroelectric switching behavior. The Sc content, x, varied in the examples from about 0.14 to about 0.36.

The Sc content may fall outside this range in other examples.

As described herein, the growth conditions (e.g., the growth temperature) are controlled to reduce (e.g., minimize) the formation of leakage current paths. The reduction of leakage current paths is useful for establishing the ferroelectricity of the layers.

The P-E loops shown in Part B of FIG. 1 were collected with a triangular voltage input with a frequency of 40 kHz. All of the ScₓAl₁₋ₓN films exhibited a clear hysteresis loop attributable to ferroelectricity, indicating a distinct ferroelectric polarization inversion across the entire Sc content range referenced above. The near-ideal box-like shape of each of the P-E loops indicates uniform incorporation of Sc and high crystal quality. Because the wurtzite structure possesses strong spontaneous polarization only along the c-axis, the domain rotation is configured for 180°, which enhances the coercive field significantly compared with other ferroelectric materials, such as PZT and In₂Se₃. The non-closed P-E loops and the indistinct polarization saturation for some of the examples can be attributed to the non-negligible leakage currents at very high electric fields. No leakage current compensation was applied to the data presented herein.

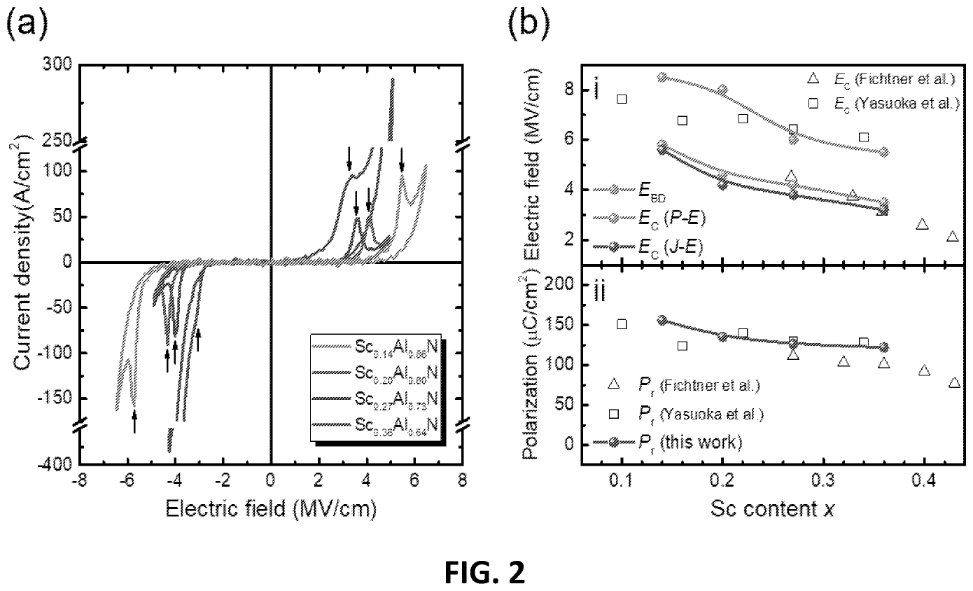

Part A of FIG. 2 depicts the corresponding J-E loops measured with the same triangular voltage input with a frequency of 10 kHz. The ferroelectricity of each of the ScₓAl₁₋ₓN film examples is unambiguously supported by instances of the switching current. Each instance is indicated by a respective black arrow in the graphical plot. The increase of current density when applying a large electric field above the level of the coercive field E_{C}, especially for Sc_{0.14}Al_{0.86}N and Sc_{0.36}Al_{0.64}N, indicates a large contribution from the leakage current. Nevertheless, current bumps due to electric dipole switching are still shown in the graphical plot. In this set of examples, the Sc_{0.36}Al_{0.64}N film exhibits the largest leakage current. This is mainly due to the degeneration of material quality and reduction of band gap with increasing Sc incorporation. Defect formations, such as high densities of threading dislocations, stacking faults, and point defects can act as leakage paths. Notwithstanding such leakage paths, layers of ScₓAl₁₋ₓN with lower (e.g., x less than or equal to about 0.10) and higher Sc content (e.g., x greater than or equal to 0.40) may also exhibit ferroelectric switching behavior.

Part B(i) of FIG. 2 depicts mean coercive fields levels for examples over a range of Sc content levels. The mean coercive field [E_{C}=(E⁺_{C}−E⁻_{C})/2] of ScₓAl₁₋ₓN films may be deduced from the P-E and J-E loops shown in Part B of FIG. 1 and Part A of FIG. 2.

The E_{C} values reported by Fichtner et al. (measured at 711 Hz) 15 and Yasuoka et al. (measured at 100 kHz) are also plotted in Part B(i) of FIG. 2 for comparison. It has been experimentally demonstrated that the distortion of the robust wurtzite structure with increasing Sc content, i.e., shift of the internal u parameter towards the value for hexagonal structure (u=½), facilities polarization switching. Therefore, the nearly linear reduction of E_{C}, from about 5.7 MV/cm (Sc_{0.14}Al_{0.86}N) to about 3.4 MV/cm (Sc_{0.36}Al_{0.64}N), is believed to arise from the gradual lowering of the polarization switching barrier with increasing Sc content. It is also noticed that the E_{C} estimated from J-E loops is slightly lower than that acquired from the P-E loops. This is due to the different frequencies used for the P-E (40 kHz) and J-E (10 kHz) measurements. Normally, a relatively large electric field is used for polarization switching when applying a short pulse, that is, employing a high measurement frequency results in an increase of E_{C}. Considering the effect of measurement frequency, the E_{C} values for these examples of MBE grown ScₓAl₁₋ₓN films agree well with previous reports on ScₓAl₁₋ₓN formed by sputter deposition.

Part B(i) also depicts the average breakdown fields E_{B}D of the ScₓAl₁₋ₓN examples acquired from five electrodes. The breakdown field levels are found to be around 2-3 MV/cm higher than the coercive field for each Sc content level, thereby enabling the polarization switching before dielectric breakdown occurs. This corresponds to a figure of merit ratio (E_{BD}/E_{C}) up to about 1.9, which is better than that exhibited by ScₓAl₁₋ₓN films formed via sputter deposition.

Part B(ii) of FIG. 2 depicts the remnant polarization Pᵣ obtained from the P-E loop data. The Pᵣ values reported by Fichtner et al. and Yasuoka et al. are also plotted for comparison. The Pᵣ values monotonically decline with the increase of Sc content. The extrapolated Pᵣ for Sc_{0.20}Al_{0.30}N is about 135 μC/cm2, demonstrating the large remnant polarization for the epitaxially grown ScₓAl₁₋ₓN films or layers of the disclosed methods and devices.

Due to the large lattice mismatch between sapphire and GaN, large densities of defects may exist in epitaxial GaN and the ScₓAl₁₋ₓN/GaN heterointerface. To rule out that the hysteresis behavior may be related to any trap charging and discharging processes, retention testing was performed to reveal the stability of the polarization after switching.

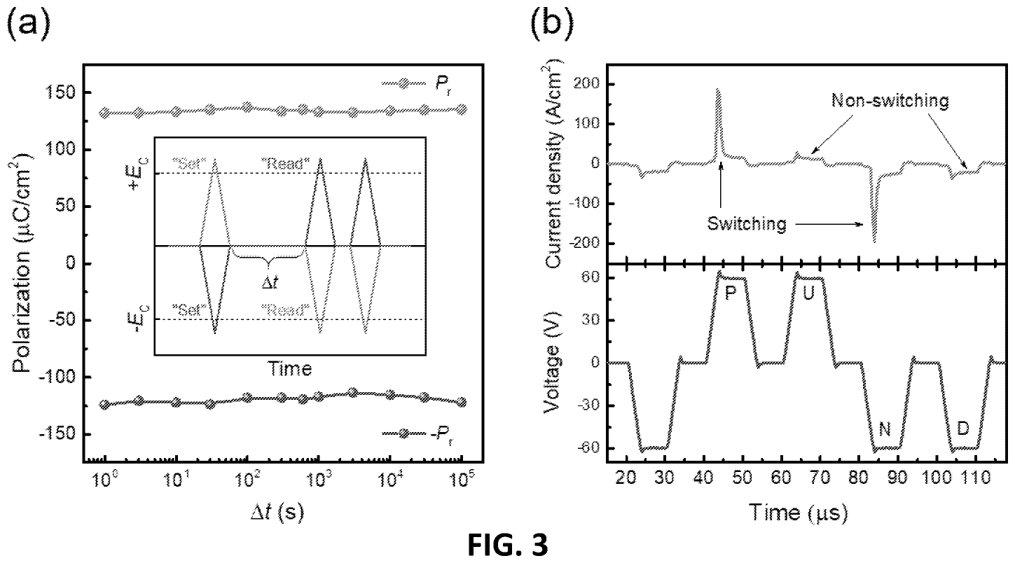

Part A of FIG. 3 displays the retention behavior of an example involving a Sc_{0.20}Al_{0.80}N layer. The remnant polarization in both directions (Pᵣ and −Pᵣ) stayed almost unchanged over 10⁵ seconds (s), indicating little polarization loss and thereby eliminating the possibility of trap-charging effects. The inset shows the voltage pulse sequences used for the retention tests.

Part B of FIG. 3 depicts transient current-voltage profiles during PUND measurements to probe the polarization switching speed of an example of epitaxially grown ScₓAl₁₋ₓN film. In this case, the PUND measurements were captured for the Sc_{0.20}Al_{0.30}N film at 6 MV/cm. Distinct current peaks can be observed in the “P” and “N” sequences. It is also noticed that the current peaks are followed by a stair-like tail, which is mainly from resistive leakage. A sudden current response was measured immediately after the drive voltage saturated, indicating that the polarization switching time is likely significantly smaller than the resolution of the current experimental setup (500 ns).

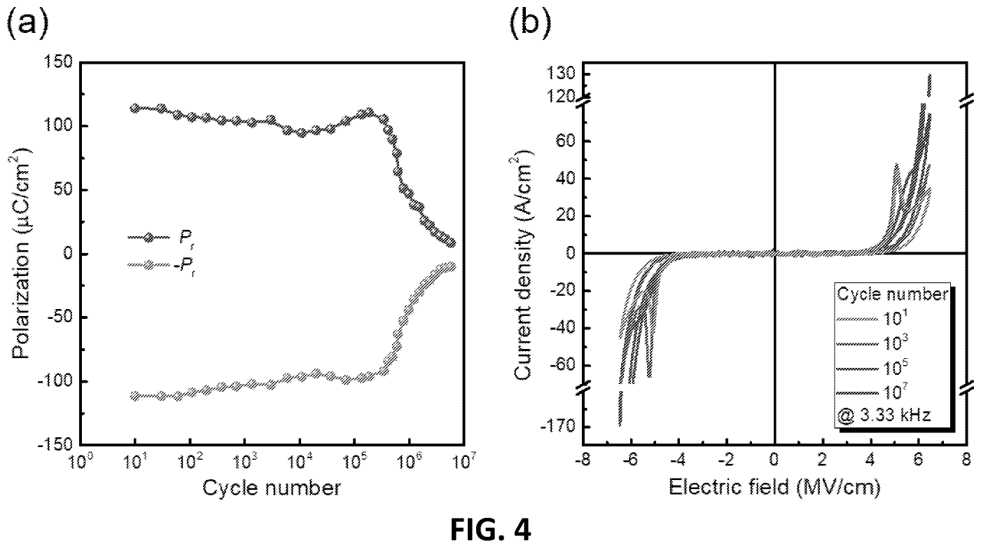

Endurance testing was conducted under 6 MV/cm pulses with a pulse width of 10 μs to capture the systematic loss of switchable polarization in a Sc_{0.20}Al_{0.30}N example film under repetitive bipolar cycling. The pulse sequences were pre-executed to make sure that the ferroelectric dipoles were sufficiently realigned under the selected pulse profile. As shown in Part A of FIG. 4, no apparent fatigue behavior can be found with up to about 3×10⁵ switching cycles, which is more than one order of magnitude higher than that of the ScₓAl₁₋ₓN films formed by sputter deposition, and is comparable with conventional ferroelectric materials. After that, the remnant polarization slowly becomes larger and then drops and almost disappears after about 10⁷ switching cycles.

Part B of FIG. 4 shows the J-E loops recorded after 10, 10³, 10⁵, and 10⁷ switching cycles. The polarization switching current gradually decreases and becomes almost invisible with increasing cycle number, while the resistive leakage current exhibits an observable rise. An unexpected increment of coercive field is also measured. The gradual loss of polarization as well as the diminishing of switching current indicates that the polarization fatigue may result from progressive domain wall stabilization by mobile point defects during cycling. This result differs from the fatigue behavior observed on sputter-deposited ScₓAl₁₋ₓN films, in which breakdown occurs after electrical cycling.

Ferroelectricity of ScₓAl₁₋ₓN grown by an epitaxial procedure such as MBE has been achieved. Ferroelectric switching is unambiguously confirmed by systematic electrical measurements on ScₓAl₁₋ₓN films over a Sc content range of about 0.14 to about 0.36. In one case, Sc_{0.20}Al_{0.30}N shows a coercive field of 4.2 MV/cm at 10 kHz and a large remnant polarization of 135 μC/cm2. More importantly, the endurance tests exhibit no apparent polarization loss in up to 3×10⁵ switching cycles.

The achievement of epitaxial ferroelectric III-nitride layers (e.g., semiconductor layers), as disclosed herein, may be used to support new and/or improved functionality in III-nitride semiconductor device technologies. A number of examples are described herein. The epitaxial growth of ferroelectric III-nitride layers also creates a number of new device configurations in which ferroelectric functionality is integrated (e.g., seamlessly integrated) into electronic, photonic, optoelectronic, photoelectrochemical, and other devices and systems.

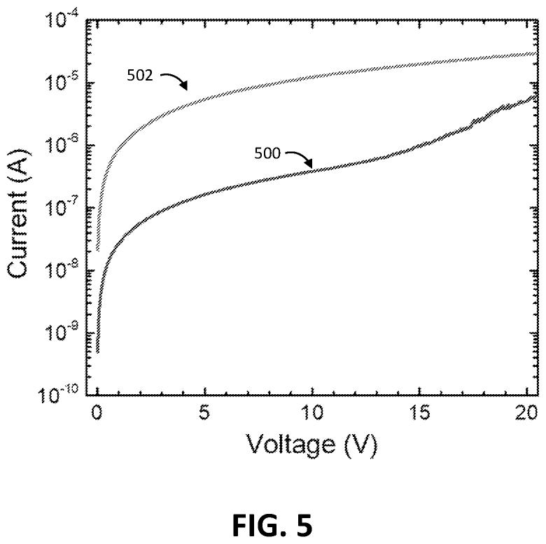

FIG. 5 depicts a comparison of leakage current levels 500, 502 for two ScₓAl₁₋ₓN layers with a same Sc content fabricated in accordance with two examples. The leakage current levels 500, 502 are plotted as a function of applied voltage. One of the wurtzite ScₓAl₁₋ₓN layers was grown with the optimized conditions (e.g., within the growth temperature ranges described herein), and exhibits a leakage current level 500 more than one order of magnitude lower than a leakage current level 502 exhibited by the other layer, which was grown with non-optimized conditions (e.g., above the growth temperature ranges described herein). The significantly reduced leakage current at the level 500 makes it possible to apply an electric field beyond the coercive field of the ScₓAl₁₋ₓN layer, thereby enabling the realization of ferroelectric switching.

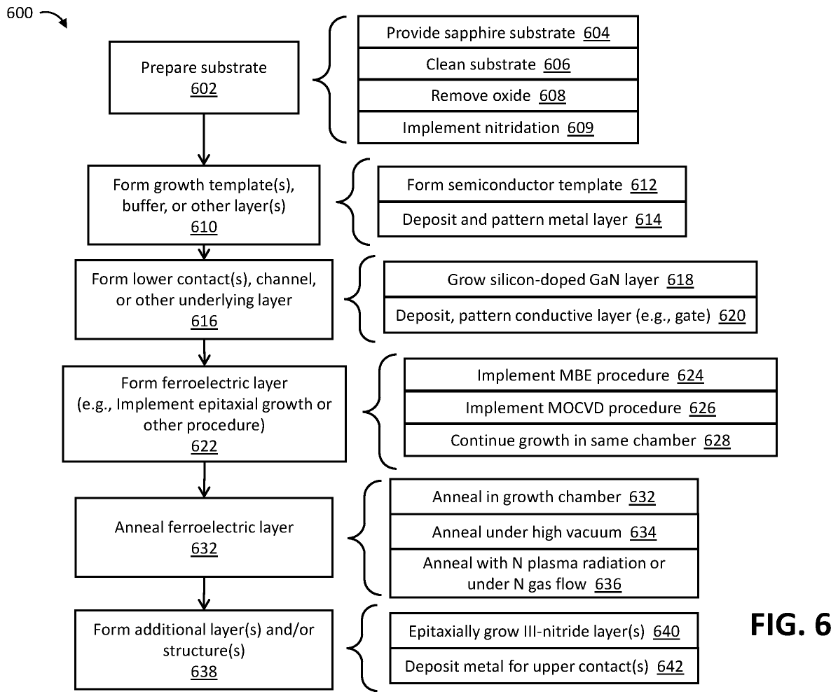

FIG. 6 depicts a method 600 of fabricating a heterostructure having a wurtzite structure of an alloy of a III-nitride material with scandium incorporated therein in accordance with one example. As described herein, the method 600 is configured such that the wurtzite structure exhibits ferroelectric behavior. The heterostructure may form a device, or a part of a device, in which one or more layers or regions of the device exhibit the ferroelectric behavior. The method 600 may be used to fabricate the examples of ScₓAl₁₋ₓN films and layers described herein.

The method 600 may begin with an act 602 in which a substrate is prepared and/or otherwise provided. In some cases, the act 602 includes providing a sapphire substrate in an act 604. The sapphire substrate may have an on-axis, or off-axis, c-plane at the growth front. The act 604 may include patterning or otherwise processing the substrate to establish an off-cut angle. The sapphire substrate may thus be or include off-cut sapphire. Additional or alternative patterning of the substrate may be used to configure the substrate to reduce defect formation in subsequently grown layers of the heterostructure and/or otherwise improve material quality therein. Such processing may also facilitate the formation of a heterostructure having alternating regions of metal- and nitrogen-polarity.

Alternative or additional substrate materials may be used, including, for instance, silicon, bulk GaN, bulk AlN, or other semiconductor material. Still other materials may be used, including, for instance, silicon carbide. The substrate may be cleaned in an act 606. In some cases, a native or other oxide layer may be removed from a substrate surface in an act 608. In the example of FIG. 6 (e.g., sapphire examples), the act 602 may include implementing a nitridation procedure in an act 609. Additional or alternative processing may be implemented in other cases, including, for instance, doping or deposition procedures. The substrate thus may or may not have a uniform composition. The substrate may be a uniform or composite structure.

In an act 610, one or more growth templates, buffer, or other layers are formed. The layer(s) are thus formed on, or otherwise supported by, the substrate. The layer(s) may or may not be in contact with the substrate. In some cases, the layer(s) are composed of, or otherwise include, a semiconductor material. For instance, the act 610 may include an act 612 in which a semiconductor layer is formed. For example, a III-nitride layer, such as a GaN layer, may be grown or otherwise formed on the substrate. Other compound or other semiconductor materials may be used, including, for instance, AlGaN. The semiconductor layer(s) may be N-polar, metal-polar, or alternating or otherwise mixed polarity (e.g., periodically poled structures). The semiconductor layer(s) may form a part of the heterostructure underlying the ferroelectric layer to be grown. The semiconductor layer be undoped or doped (e.g., Si-doped). The act 612 may thus be implemented before (e.g., in preparation for) implementing an epitaxial growth procedure in which a wurtzite structure is formed. The wurtzite structure may thus be formed on the semiconductor layer. The semiconductor layer may be configured or used as a growth template for the wurtzite structure and/or other elements of the heterostructure. In some cases, the act 612 may include growing the semiconductor layer in an epitaxial growth chamber in which the epitaxial growth procedure for the wurtzite structure is implemented. As a result, the substrate may remain within, e.g., is not removed from, the epitaxial growth chamber between forming the semiconductor layer and implementing the epitaxial growth procedure for growing the wurtzite structure.

Alternatively or additionally, the act 610 includes an act 614 in which one or more metal or other conductive layers are deposited and patterned. For example, an aluminum layer may be deposited on a silicon substrate in preparation for the epitaxial growth of the wurtzite structure.

The method 600 may include an act 616 in which one or more contacts or other layers are formed. The layer(s) may form a part of the heterostructure underlying the ferroelectric layer to be grown. Examples of the underlying layer(s) include a lower or bottom contact of the heterostructure or a channel layer of the heterostructure. The nature of the underlying layer(s) may vary with the device being fabricated. The Si-doped layer may or may not be grown on top of the template or buffer layer formed in the act 610. In the example of FIG. 6, the act 616 includes growing a silicon-doped GaN layer in an act 618. The Si-doped GaN layer may be N-polar or metal-polar. Other materials may be used. For instance, the underlying layer(s) may be composed of, or otherwise include, AlGaN, InAlN, InGaN, or InAlGaN. Still other materials may be used. For instance, a channel layer may be composed of, or otherwise include, other types of semiconductors, e.g., Ga₂O₃, diamond, Si, SiGe, GaAs, InGaAs, or InP, in addition to one or more of the above-referenced III-nitride alloys, Additional or alternative conductive structures, such as a gate structure, may be deposited and/or patterned in an act 620.

In an act 622, a non-sputtered epitaxial growth procedure is implemented at a growth temperature to form a wurtzite structure supported by the substrate. As described herein, the wurtzite structure is composed of, or otherwise includes, an alloy of a III-nitride material. For instance, the III-nitride material may be AlN. Additional or alternative III-nitride materials may be used, including, for instance, gallium nitride (GaN), indium nitride (InN), and their alloys. As also described herein, the epitaxial growth procedure is configured to incorporate scandium and/or another group IIIB element into the alloy of the III-nitride material. The alloy may thus be ScₓAl₁₋ₓN, for example. In some cases, the act 622 includes an act 624 in which an MBE procedure is implemented. In other cases, an MOCVD or other non-sputtered epitaxial growth procedure is implemented in an act 626.

The act 622 may constitute a continuation, or part of a sequence, of growth procedures. The growth procedures may be implemented in a common, or same, growth chamber. The act 622 may thus include an act 628 in which epitaxial growth is continued in the same chamber in which one or more other layers of the heterostructure were grown. For instance, one or more of the growth template and the underlying semiconductor layer(s) formed in the acts 610 and 616 may be formed in the same chamber as the ferroelectric layer. Sequential layers of the heterostructure may thus be grown without exposure to the ambient. The quality of the interface between the layers may accordingly be improved.

The growth temperature may be at a level such that the wurtzite structure exhibits a breakdown field strength greater than a ferroelectric coercive field strength of the wurtzite structure. Ferroelectric switching and other behavior may thus be achieved.

The growth temperature is at a level lower than what would be expected given the III-nitride material. In some examples, the growth temperature level is significantly less than the temperature at which the III-nitride material would typically be grown. For instance, the growth temperature level may be such that attempts to grow a structure composed of the III-nitride material (i.e., without scandium) at the growth temperature level would not be worthwhile. The resulting structure would be of such poor quality (e.g., possess far too many defects) to be useful. Growth of a single crystal of the scandium-including alloy (e.g., a monocrystalline layer of the alloy) at the growth temperature level may nonetheless be achieved. For example, in some cases, a ScₓAl₁₋ₓN alloy may be epitaxially grown at a growth temperature of about 650 degrees Celsius despite that the corresponding (scandium-free) III-nitride material, AlN, is conventionally grown at much higher temperatures, e.g., about 1000 degrees Celsius. Conversely, attempts to grow AlN at about 650 degrees Celsius or lower would result in structures of such poor quality so as to be useless. In contrast, the epitaxially grown ScₓAl₁₋ₓN layer grown at that low temperature is unexpectedly monocrystalline and of high quality.

Growth of the ScₓAl₁₋ₓN layer at the conventional AlN growth temperature (and other temperatures above the upper bound) unexpectedly results in the formation of dislocations and/or other leakage paths in the ScₓAl₁₋ₓN layer. With the leakage paths, the ScₓAl₁₋ₓN layer has a breakdown field strength level too low (e.g., below the ferroelectric coercive field strength level). The layer accordingly does not exhibit ferroelectric behavior.

In some cases, the growth temperature may be about 650 degrees Celsius or less. The growth temperature may correspond with the temperature measured at a thermocouple in the growth chamber. The growth temperature at the epitaxial surface may be slightly different. The growth temperature is accordingly approximated via the temperature measurement at the thermocouple.

The upper bound of the growth temperature range may vary in accordance with the alloy and/or the epitaxial growth technique. For instance, in other cases, the upper bound on the growth temperature may be higher, such as about 680 degrees Celsius, or about 690 degrees Celsius. In still other cases, the upper bound may be lower, including, for instance, about 600 degrees Celsius or about 620 degrees Celsius.

At each level within the above-described ranges of suitable growth temperatures, the resulting wurtzite structure is monocrystalline. The resulting wurtzite structure is monocrystalline to a degree not realizable via, for instance, sputtering-based procedures for forming ScₓAl₁₋ₓN layers. Such procedures are only capable of producing structures with x-ray diffraction rocking curve line widths on the order of a few degrees at best. In contrast, the structures grown by the disclosed methods exhibit x-ray diffraction rocking curve line widths on the order of a few hundred arc-seconds or less, well over an order of magnitude less. In this manner, leakage current paths are minimized or otherwise sufficiently reduced so that the resulting wurtzite structure has a suitably high breakdown field strength level, e.g., sufficiently greater than the ferroelectric coercive field strength.

The above-noted differences in crystal quality evidenced via x-ray diffraction rocking curve line widths may also be used to distinguish between monocrystalline and polycrystalline structures. As used herein, the term “polycrystalline” refers to structures having x-ray diffraction rocking curve line widths on the order of a few degrees or higher. As used herein, the term “monocrystalline” refers to structures having x-ray diffraction rocking curve line widths at least one order of magnitude lower than the order of a few degrees.

Comparing the wurtzite structures of the layers grown by MBE or other non-sputtered techniques (e.g., MOCVD or HVPE) with sputtering deposition techniques, the microstructure of the former techniques is more uniform with highly ordered stacking sequence of atoms. In sputter deposited layers, domains with cubic phase or domains with in-plane mis-orientation are readily observed. The existence of these mis-aligned domains suppresses the complete switching of polarization, and further results in the fast loss of polarization during fatigue testing. Regarding phase purity, the highly crystallographic orientation of layers grown by MBE or other non-sputtered techniques exhibits more repeatable ferroelectric switching, which is useful in a number of device applications.

The wurtzite structure of the ferroelectric layer may be nitrogen-polar (N-polar) or metal-polar. The polarity of an underlying layer formed in the act 610 and/or the act 616 may be used to establish the polarity of the ferroelectric layer formed in the act 622. As described herein, the polarity of the underlying layer may, in turn, be established by a characteristic of the substrate. The polarity may continue across the interface between the underlying layer and the ferroelectric layer. Either N- or metal-polarity may thus persist as the composition changes from the underlying layer to the ferroelectric layer.

The wurtzite structure may then be annealed in an act 630. The annealing may be implemented at a temperature greater than the growth temperature. In some cases, the annealing temperature falls in a range from about 700 Celsius to about 1500 degrees Celsius. Examples of films prepared with such annealing exhibited stable polarization switching with further reduced leakage current relative to non-annealed films. Film or device uniformity was also improved via the annealing, thereby further improving the polarization switching behavior of the ferroelectric Sc-III-N alloys. The underlying mechanism for the improved performance and uniformity with annealing is attributed to the reduced threading dislocation density and defect density, which usually act as electric leakage paths. Such usefulness of the post-growth annealing is realized despite past concerns that high processing temperatures can lead to a loss of ferroelectricity.

Such post-growth high-temperature annealing of ScₓAl₁₋ₓN may be performed in-situ in the same growth chamber (e.g., the same MBE chamber) in an act 632. In other cases, the annealing is performed ex-situ in a chamber directed to annealing procedures.

The annealing process may be implemented under high vacuum in an act 634 (e.g., in-situ in the growth chamber). In other cases, the annealing may be implemented either with nitrogen plasma radiation or under nitrogen gas flow in an act 636.

The above-described annealing procedure may be implemented in connection with films grown under any of the above-described growth conditions. For instance, the annealing procedure may be implemented after growth under slightly to moderately N-rich conditions at a growth temperature below about 650 degrees Celsius. The annealing procedure may also be implemented after growth under unbalanced flux ratios (e.g., N-rich or extreme N-rich conditions) at growth temperatures above about 650 degrees Celsius.

The method 600 may include an act 638 in which one or more layers (e.g., semiconductor layers) are formed after growth of the wurtzite structure. As a result, the layer(s) may be in contact with the wurtzite structure. For instance, one or more III-nitride (e.g., GaN or AlGaN) or other semiconductor layers may be epitaxially grown in an act 640. The act 640 may be implemented in the same epitaxial growth chamber used to grow the wurtzite structure. As a result, the substrate (and heterostructure) is not removed from the epitaxial growth chamber between implementing the acts 622 and 638.

Alternatively or additionally, the act 638 includes an act 642 in which one or more metal or other conductive layers or structures are formed. The layers or structures may be deposited or otherwise formed. In some cases, the conductive structure is configured as an upper or top contact. For instance, the conductive structure may be a gate.

The method 600 may include one or more additional acts. For example, one or more acts may be directed to forming other structures or regions of the device that includes the heterostructure. In a transistor device example, the regions may correspond with source and drain regions. The nature of the regions or structures may vary in accordance with the nature of the device.

The order of the acts of the method 600 may differ from the example shown in FIG. 6. For example, the acts 616, 618, and 620 in which contacts and/or other conductive structures formed may be implemented after the growth of the ferroelectric layer.

A number of different types of devices may be fabricated by the method 600 of FIG. 6, and/or another method of fabricating a heterostructure having a wurtzite structure of an alloy of a III-nitride material with scandium incorporated therein. For example, the ferroelectric ScₓAl₁₋ₓN or other alloy of a III-nitride material may be useful in various types of nonvolatile memory devices (e.g., FeRAM, FeFET, FTJ, and FeSFET devices), various types of reconfigurable electronic and other devices (e.g., Fe-HEMT, Fe-capacitor, and SAW devices), various types of photodetection, photovoltaic and optoelectronic devices (e.g., self-driven photodetector and solar cell devices), and various homojunction devices (e.g., devices that use a laterally distributed charge plate to tune the Fermi level in adjacent layers). Still other types of devices may be fabricated, including, for instance, FE-based thin-film bulk acoustic wave resonators (FBAR) devices.

A number of example devices are now described. In each example, the device includes a substrate and a heterostructure supported by the substrate. The heterostructure includes a monocrystalline layer of an alloy of a III-nitride material. As described herein, the alloy includes scandium. As also described herein, the monocrystalline layer exhibits a breakdown field strength greater than a ferroelectric coercive field strength of the monocrystalline layer. In some cases, the III-nitride material is aluminum nitride (AlN), but other III-nitrides may be used.

In some of the devices described below, the device also includes a semiconductor layer disposed between the substrate and the heterostructure. The semiconductor layer may include a further III-nitride material, such as GaN. In some cases, the semiconductor layer is in contact with the heterostructure. The epitaxial growth of the layers may result in a high quality interface between the layers. Alternatively or additionally, the device also includes a metal or other conductive layer disposed between the substrate and the heterostructure. The metal layer may be in contact with the heterostructure, examples of which are described below.

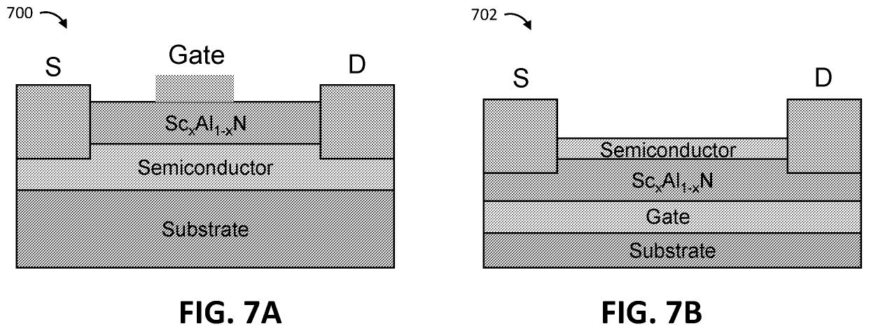

FIGS. 7A and 7B depict examples of FeFET memory devices 700, 702. In each device 700, 702, a ferroelectric ScₓAl₁₋ₓN layer is disposed between a gate electrode and a source-drain conduction region. The ferroelectric layer provides a reversible electrical state for a transistor of the device. The large remnant electrical field polarization in the ferroelectric ScₓAl₁₋ₓN layer retains the state of the transistor (e.g., on or off) in the absence of any electrical bias to form a single transistor nonvolatile memory. In some cases, bulk and/or other semiconductor channel layers are composed of, or otherwise include, GaN or silicon, or two-dimensional materials like MoS₂ or graphene. In each device 700, 702, the FeFET memory device 700, 702 may include a heterostructure including, for instance, the ferroelectric ScₓAl₁₋ₓN or other alloy of a III-nitride material, along with one or more layers of a III-nitride semiconductor, such as AlN, as the gate dielectric and barrier. The substrate supporting these layers and structures of the devices may be composed of, or otherwise include, for instance, GaN or silicon. The control terminal or gate may be disposed above or below the heterostructure as shown.

Other types of memory devices include one transistor one capacitor (1T-1C) FeRAM devices. For example, a FeRAM device may include a MIM ferroelectric capacitor composed of, or otherwise including, Al, ScₓAl₁₋ₓN, and Al supported by a pre-processed silicon or GaN substrate.

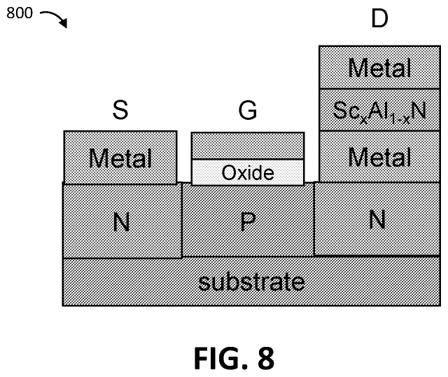

FIG. 8 depicts a coupled FET structure 800 configured as a memory cell. During the switching of the remnant polarization state in a ScₓAl₁₋ₓN layer, a current pulse is generated to indicate the stored binary information in the cell.

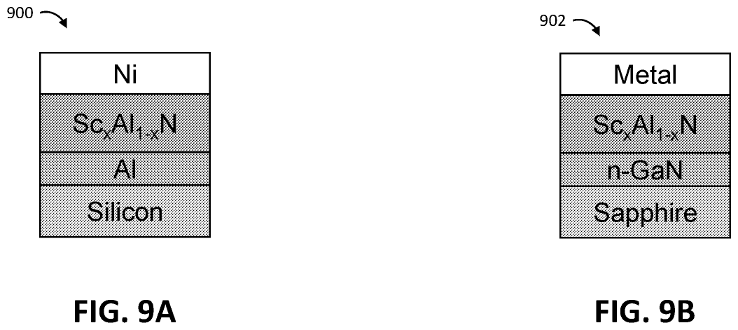

FIGS. 9A and 9B depict examples of FTJ memory devices 900, 902. In the example device 900, an epitaxially grown ferroelectric layer is disposed between metal layers (e.g., nickel and aluminum layers). In the other example device 902, the ferroelectric layer is disposed between a III-nitride semiconductor layer (e.g., n-type doped GaN) and a metal layer. Other metal-Fe (insulator)-metal and metal-(insulator)-Fe-(insulator)-semiconductor configurations may be used. In these example devices 900, 902, the ScₓAl₁₋ₓN or other alloy provides the ferroelectricity and tunes the ON/OFF current/resistance ratio as a memorizer readout.

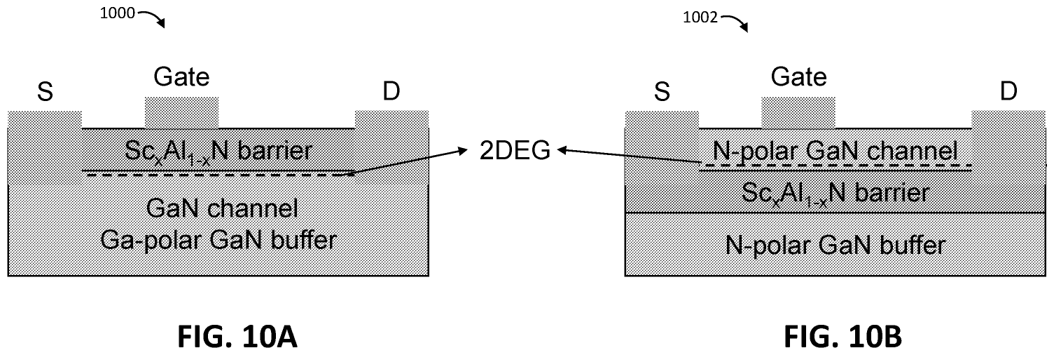

FIGS. 10A and 10B depict examples of metal-polar and N-polar Fe-HEMT devices 1000, 1002, respectively. In these two examples, each of the devices 1000, 1002 includes a heterostructure composed of, or otherwise including, a stack of ferroelectric ScₓAl₁₋ₓN, channel, and buffer layers. The order or arrangement of the layers varies as shown between the metal-polar and N-polar examples. The heterostructure may include additional, fewer, or alternative layers. For instance, the N-polar buffer layer shown in the device 1002 of FIG. 10B may be grown on an additional, underlying Si-doped N-polar III-nitride layer, such as an Si-doped, N-polar GaN layer.

The heterostructure may be grown on a bulk or other region composed of, or otherwise including, a III-nitride semiconductor material, such as GaN. One or more of the III-nitride semiconductor layers may be doped, e.g., Si or otherwise n-type doped. Other III-nitride semiconductors may be used, including, for instance, AlGaN, InGaN, and InAlGaN as described herein. A switchable two-dimensional electron gas (2DEG) heterojunction may thus be formed due to the strong spontaneous polarization in the ScₓAl₁₋ₓN layer during operation as shown. A thin AlN layer may be inserted between the ScₓAl₁₋ₓN and channel layers to enhance carrier mobility.

Still other types of transistor devices may utilize the epitaxially grown ferroelectric layers described herein, including, for instance, N-polar bottom-gated and gate-recessed transistor devices, both with and without a gate oxide layer.

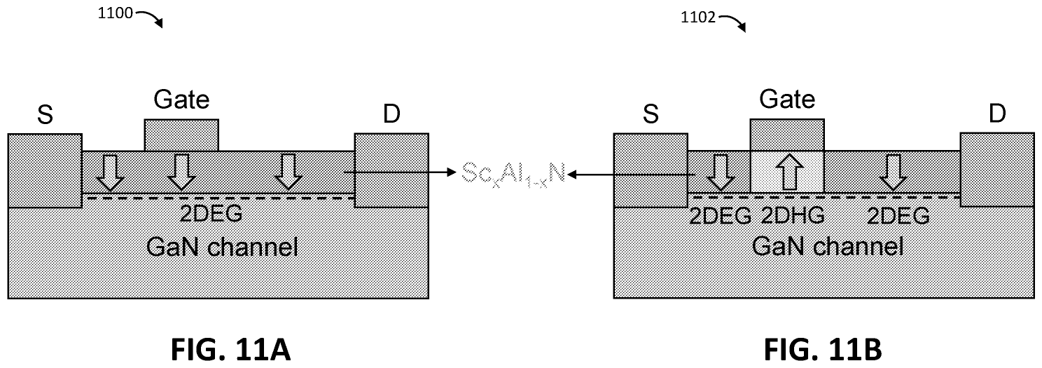

FIGS. 11A and 11B depict examples of reconfigurable Fe-HEMT devices 1100, 1102. In these example, each of the devices 1100, 1102 includes a heterostructure with a ferroelectric ScₓAl₁₋ₓN layer. As shown in FIG. 11A, the heterostructure may include a stack of ferroelectric ScₓAl₁₋ₓN and channel layers, in which the polarization of the ferroelectric ScₓAl₁₋ₓN layer can be switched. Alternatively, the heterostructure may be configured such that a 2DHG or depletion region underlying the polarization switched region is formed, as shown in FIG. 11B. The disclosed devices include still other types of reconfigurable Fe-HEMT devices, including, for instance, Fe-HEMT devices including the N-polar structure depicted in FIG. 10B.

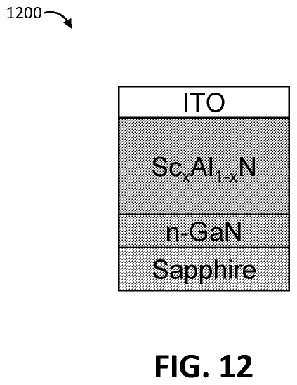

FIG. 12 depicts an example of a photovoltaic device 1200 in which a ferroelectric layer is integrated into a heterostructure having one or more III-nitride layers between electrodes of the device. In the example shown, the heterostructure includes an n-type GaN layer adjacent to, and in contact with a ScₓAl₁₋ₓN layer. An indium tin oxide (ITO) layer establishes one of the electrodes (e.g., a transparent cathode or anode) of the device. Photon-generated carriers in the ScₓAl₁₋ₓN layer are separated and collected by the polarization-induced electric field. The heterostructure may be supported by a sapphire or other substrate.

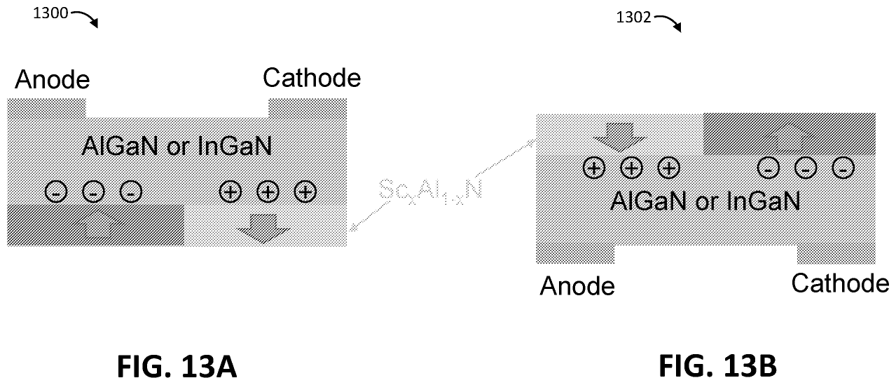

FIGS. 13A and 13B depict further examples of photovoltaic devices 1300, 1302.

In each example, the polarization in a ferroelectric layer attracts electron/hole charges to different regions, thereby creating a built-in electric field in a light-absorption layer and helping to separate and collect the photon-generated carriers.

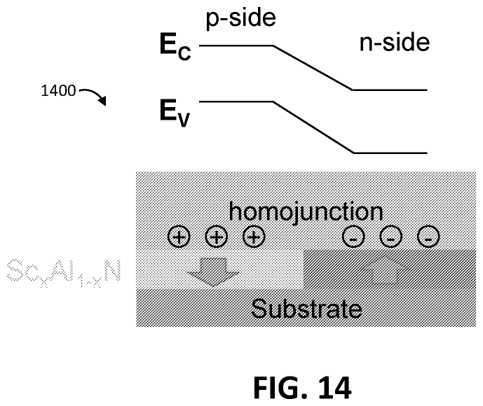

FIG. 14 depicts an example of a homojunction device 1400 having a ferroelectric layer adjacent a channel layer or region. The modulated polarization in the ferroelectric layer attracts electrons and holes in opposite directions, thereby forming a lateral homo p-n junction inside the channel material. The homojunction may be formed in semiconductors such as GaN, Si and two-dimensional materials.

Described above are devices and structures exhibiting ferroelectricity, e.g., in layers of ScₓAl₁₋ₓN. Methods for growing the structures are also described, including methods involving, for instance, plasma-assisted molecular beam epitaxy on GaN templates. Distinct polarization switching is unambiguously observed for ScₓAl₁₋ₓN films with Sc content in the range of, e.g., 0.14-0.36. Examples of Sc_{0.20}Al_{0.30}N, which is nearly lattice-matched with GaN, were found to exhibit a coercive field of about 4.2 MV/cm at 10 kHz and a remnant polarization of about 135 μC/cm². After electrical poling, an example of Sc_{0.20}Al_{0.30}N presented a polarization retention time beyond 10⁵ seconds. Furthermore, no apparent fatigue behavior was found with up to 3×10⁵ switching cycles. The realization of ferroelectric III-V semiconductors using molecular beam and other epitaxy allows for thickness scaling, e.g., into the nanometer regime, as well as integration of high-performance ferroelectric functionality with well-established semiconductor platforms for a broad range of electronic, optoelectronic, and photonic device applications.

Described below are further examples of devices having heterostructures with a ferroelectric layer formed via the MBE or other non-sputtered, epitaxial growth procedures and fabrication methods described herein. In these examples, the heterostructures include one or more nitrogen-polar (N-polar) layers. Although described in connection with examples having GaN/ScAlN heterostructures, the composition of the layers of the heterostructures may vary as described herein. The heterostructures may include additional or alternative layers. For instance, ferroelectric N-polar ScAlN may also be formed on Si substrates by incorporating a N-polar GaN buffer layer into the heterostructure.

By alloying aluminum nitride (AlN) with scandium (Sc), the resulting wurtzite ScAlN can exhibit switchable polarization with significantly enhanced electrical, piezoelectric, and linear and nonlinear optical properties. ScAlN has a tunable, direct energy bandgap in a large part of the ultraviolet (UV) spectrum and is lattice-matched to GaN for a Sc content of about 0.18. The piezoelectric coefficient d₃₃ and permittivity of Sc_{0.4}Al_{0.6}N are nearly five and two times larger than that of AlN, respectively. ScAlN possesses unusually large optical X⁽²⁾ nonlinearity, which was measured to be over one order of magnitude higher than AlN and twice the value of the extensively studied LiNbO₃. These unique characteristics, together with its ultrawide bandgap, ferroelectric functionality, and seamless integration with III-nitride technology, have made ScAlN one of the most promising materials for future high-power and high-frequency electronics, acoustic resonators and filters, micro-electromechanical systems (MEMs), neuromorphic and edge computing, quantum photonic circuits, and quantum transduction from microwave to infrared, visible and ultraviolet, to name just a few.

As described herein, growth of single-crystalline ScAlN has been achieved via molecular beam epitaxy (MBE) and metal-organic chemical vapor deposition (MOCVD). With the resulting improvements in material quality, fully epitaxial ferroelectric ScAlN has been demonstrated.

The epitaxial growth procedures described herein support the formation of both metal (M)-polar ScAlN and nitrogen (N)-polar ScAlN. Further details regarding examples of fully epitaxial ferroelectric N-polar ScAlN are provided below.

The examples of N-polar III-nitride heterostructures and nanostructures are useful in a broad range of device applications. For instance, N-polar high electron mobility transistors (HEMTs) are useful in several ways, including enhanced confinement of the two-dimension electron gas (2DEG), reduced contact resistance, and better gate control (e.g., as compared to M-polar devices). Other devices may incorporate periodical or other changes of the surface polarity. For instance, periodical change is useful for second harmonic generation. N-polar III-nitride light emitting diode (LED) devices offer several performance benefits, as compared to conventional M-polar devices, including reduced electron overflow and significantly enhanced efficiency for devices at the nanoscale. The ability to control and tune the surface polarity of ferroelectric ScAlN is also useful in acoustic wave filter applications (e.g., in 5G and 6G communications).

Examples of ferroelectric switching in N-polar ScAlN/GaN heterostructures grown on on-axis c-plane sapphire substrates using MBE are described below. The exactly aligned orientation, both out-of-plane and in-plane, between a ScAlN epilayer, a GaN buffer, and an underlying sapphire substrate were confirmed using x-ray diffraction (XRD) measurements. The ferroelectric switching behaviors of the resulting N-polar ScAlN films were studied in detail using J-E and P-E (current density and polarization over electric field, respectively), standard positive-up and negative-down (PUND), and C-V (capacitance-voltage) measurements, as well as retention and fatigue tests. A coercive field of about 4.6 MV/cm (at 10 kHz) with a remnant polarization of about 90 μC/cm² was measured for N-polar Sc_{0.21}Al_{0.79}N, and stable electrical switching was achieved up to 5×10⁵ cycles. These examples support the heteroepitaxial integration of ferroelectricity in N-polar III-nitride heterostructures, which is useful in a wide variety of electronic, optoelectronic, and acoustic devices.

In the examples described below, a Veeco GENxplor MBE system equipped with a radio-frequency (RF) nitrogen plasma source and Knudsen effusion cells for Ga, Al, and Sc sources was utilized for the epitaxial growth of the N-polar ScAlN films. Commercial 2-inch on-axis c-plane sapphire (Al₂O₃) wafers were used as substrates. The sapphire substrates were baked and outgassed at 200° C. and 600° C. in the MBE load-lock and preparation chambers for 2 h, respectively, and further outgassed at 900° C. in the growth chamber for 30 min to obtain a clean surface.

Each example included a heterostructure supported by the substrate. The heterostructure included a N-polar III-nitride buffer layer supported by and in contact with the substrate, an N-polar doped III-nitride layer supported by and in contact with the buffer layer, and a N-polar ScAlN layer supported by and in contact with the doped III-nitride layer. In each example, a 500-nm-thick layer of unintentionally doped N-polar GaN was grown as the buffer layer. A 200-nm-thick Si-doped n-type GaN layer (with an electron concentration of 5×10¹⁸ cm⁻³) was then grown, followed by a 100-nm-thick ScAlN layer. In these examples, to establish a N-polar buffer layer, nitridation of a sapphire substrate was performed in situ at 400° C. The nitridation temperature may vary in other cases. The GaN buffer layer was then grown at 650° C. under N-rich conditions including a Ga beam equivalent pressure (BEP) of about 1.6×10⁻⁷ Torr and a nitrogen flow rate of 0.3 sccm. The growth of GaN epilayer was subsequently initiated at 845° C. with increased Ga BEP to maintain a stoichiometric condition to avoid the formation of Ga droplets. The foregoing growth parameters may vary in other cases.

The ScAlN and other layers of the heterostructures were grown under the conditions described herein. For instance, the N-polar ScAlN may be grown under conditions similar to those described herein for growing metal-polar ScAlN.

The Sc content for the example ScAlN films was measured to be 0.16, 0.21, 0.29, and 0.36, respectively, utilizing energy dispersive x-ray spectroscopy (EDS). Morphological and structural characterizations were performed using atomic force microscope (AFM), scanning electron microscope (SEM), and XRD.

The examples were configured as metal/ferroelectric/semiconductor capacitor devices. The MBE-grown n-type GaN layer was used as the bottom electrode, while 100/100-nm-thick Al/Pt circular top electrodes with diameters in a range of 5-50 m were deposited through a standard photolithography and lift-off process.

Ferroelectric properties were analyzed using a Radiant Precision Multiferroic II Ferroelectric Test system driven from the top electrode. Further details regarding the ferroelectric switching properties of the N-polar ScAlN/GaN heterostructures with a Sc content of 0.21 are provided below. Unless otherwise stated, the results shown are collected from devices with a top electrode diameter of 20 μm.

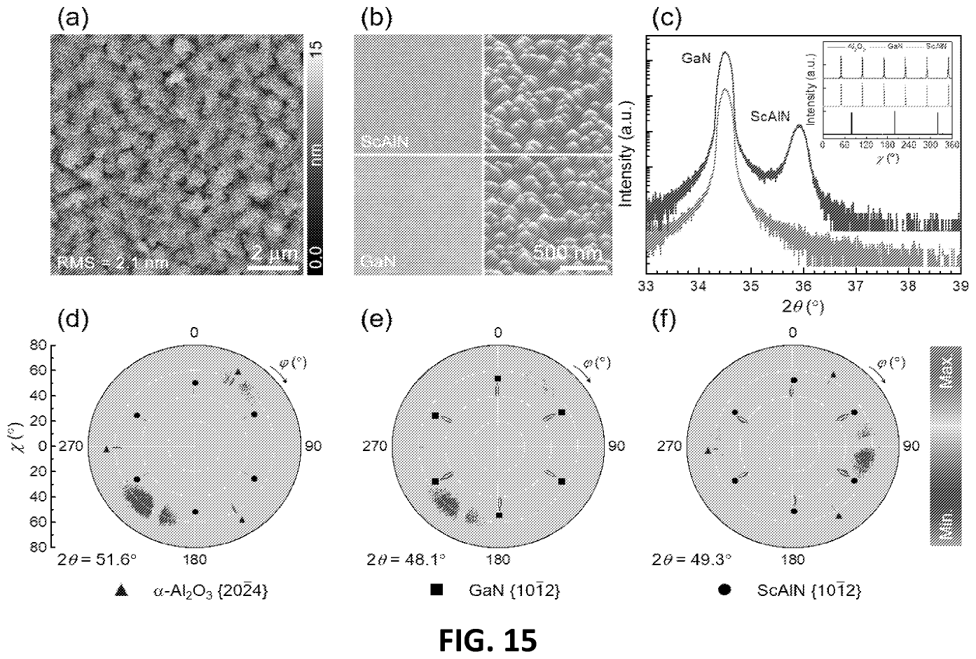

FIG. 15, part (a), shows an AFM image of an as-grown Sc_{0.21}Al_{0.79}N layer with a root mean square (RMS) roughness of 2.1 nm for a scan area of 10×10 μm². In this case, the N-polar ScAlN exhibited an island-like surface, which is inherited from that of the MBE-grown N-polar GaN/sapphire template (RMS=1.4 nm). As shown in FIG. 15, part (b), after wet chemical etching, hexagonal pyramidal nanostructures were observed on both the GaN buffer and ScAlN epilayer surfaces, confirming the as-grown N-polar lattice. The (0002) plane XRD 2θ-ω scan for Sc_{0.21}Al_{0.79}N/GaN is illustrated in FIG. 15, part (c). The wurtzite phase was confirmed by the unique diffraction peak located around 36°. The full-width-at-half-maximum (FWHM) of Sc_{0.21}Al_{0.79}N/GaN (0002) and (101̅2) planes XRD rocking curves (XRC) were determined by fitting with a pseudo-Voigt function. The XRC FWHM for Sc_{0.21}Al_{0.79}N (GaN) (0002) and (101̅2) planes are 1100 and 2800 (900 and 1800) arc sec. respectively. The estimated threading dislocation density for Sc_{0.21}Al_{0.79}N and GaN is 8.75×10¹⁰ cm⁻² and 3.35×10¹⁰ cm⁻², respectively.

The epitaxial and in-plane domain orientation relationship between the ScAlN epilayer, the GaN buffer, and the c-plane sapphire substrate were further investigated using XRD pole figure measurements. FIG. 15, parts (d)-(f), present the stereographic projections of the XRD pole figures for the {202̅4} planes of sapphire and the {101̅2} planes of GaN and Sc_{0.21}Al_{0.79}N. The 2θ angles for pole figure measurements were determined from the (101̅2) plane XRD 2θ-ω scan for the Sc_{0.21}Al_{0.79}N/GaN/sapphire sample. Three-fold symmetric spots, which correspond to the {202̅4} planes of sapphire substrate (α-Al₂O₃, triangles), and six-fold symmetric spots, which correspond to the {101̅2} planes of GaN (squares) and Sc_{0.21}Al_{0.79}N (circles), are observed. The narrow and sharp six-fold symmetric spots of ScAlN suggest that in-plane domain rotation is negligible, which is a significant benefit of epitaxial growth. The six-fold symmetry of GaN and ScAlN is rotated 30° relative to the three-fold symmetry of the sapphire substrate, while the spots for GaN and ScₓAl₁₋ₓN are aligned exactly, which is further confirmed by the (101̅2) plane XRD P scans (inset of FIG. 15, part (c)). These results indicate an epitaxial relationship of (0001)[112̅0]_{ScAlN}∥(0001)[112̅0]_{GaN}∥(0001) [11̅00]ₛₐₚₚₕᵢᵣₑ. Symmetric plane and asymmetric plane XRD measurements confirm that the MBE-grown N-polar Sc_{0.21}Al_{0.79}N layer has a single-crystalline wurtzite phase.

Small top electrodes (20 μm) with reduced parasitic capacitance were used to enable ferroelectric characterization in a high frequency range. The high measurement frequency helps suppress the leakage current during measurements. A triangular waveform PUND bias sequence with a frequency of 10 kHz was utilized to further remove the non-switching contribution and to extract the J-E and P-E loops.

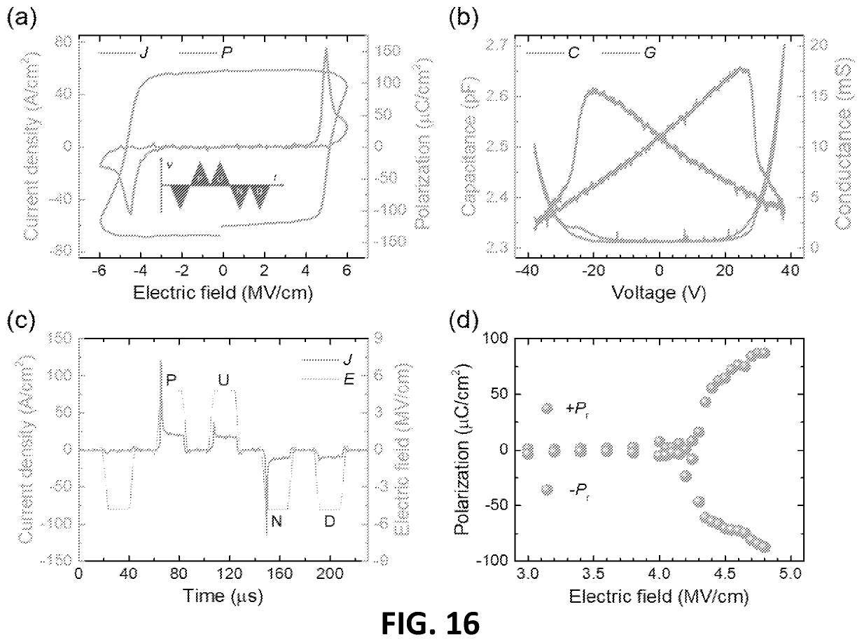

FIG. 16, part (a), shows the corresponding J-E and P-E loops extracted for the N-polar Sc_{0.21}Al_{0.79}N after subtracting the non-switching current. Well-established displacement current peaks together with the saturation of polarization upon biasing confirmed the ferroelectricity in the N-polar Sc_{0.21}Al_{0.79}N film.

FIG. 16, part (b), illustrates a C-V loop of an example N-polar Sc_{0.21}Al_{0.79}N layer. A clear butterfly shaped C-V hysteresis loop with two peaks is consistent with the characteristic C-V curves reported for ferroelectric ScAlN films and other known ferroelectrics. The corresponding turning electric field of the capacitance is smaller than the coercive field determined from the J-E and P-E loops. This is because during the C-V measurements, the operating bias voltage is increased much slower than that in the J-E and P-E measurements, although the small alternating current (AC=100 mV) field has a higher frequency (1 MHz). For a metal/ferroelectric/semiconductor capacitor, due to the possible depletion region in the semiconductor side, the measured C-V curves are generally asymmetric. The almost symmetric C-V curve here is attributed to the relatively high density of dislocations and interface/bulk defects, which help compensate the polarization charge and prohibit the depletion of the bottom n-GaN semiconductor electrode. The extracted relative dielectric constant (ε) is about 14.4 around zero bias, which is consistent with the theoretical and experimental values from previous reports. Using the above experimental results, a universal constant Pᵣ/(εE_{c}) is calculated to be about 15.7, which is consistent with most ferroelectrics, indicating the ferroelectric switching process is modulated by creep and domain-wall flow. The measured AC conductance is plotted jointly in FIG. 16, part (b).

FIG. 16, part (c), shows the current transients during a PUND measurement using square pulses (4.8 MV/cm). Clear switching currents can be identified in the switching pulse P and N, while the current during the pulse U and D represent the non-switching current arising from leakage and dielectric responses. FIG. 16, part (d), further shows the standard electric field dependent PUND measurement results, revealing a saturated remnant polarization of about 90 μC/cm², which is comparable to those obtained for M-polar ScAlN/GaN heterostructures with a similar Sc content.

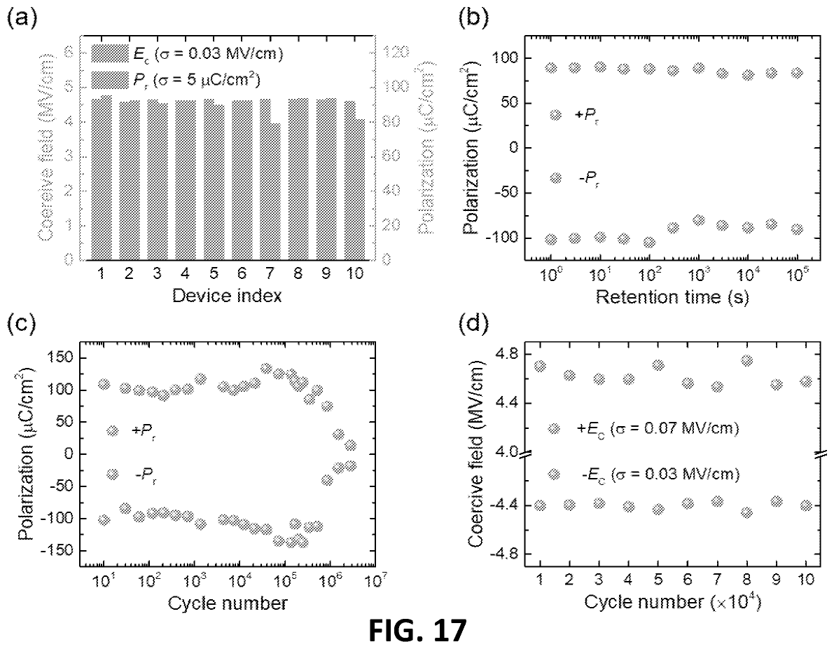

FIG. 17 is directed to the reliability of the ferroelectric polarization switching in the N-polar Sc_{0.21}Al_{0.79}N/GaN examples. FIG. 17, part (a), presents the coercive field and remnant polarization recorded from 10 devices randomly distributed across the wafer. The measured average coercive field and remnant polarization for these devices were 4.6 MV/cm and 90 μC/cm², with a standard deviation of 0.03 MV/cm and 5 μC/cm², respectively. The small standard deviation suggests that the ferroelectric polarization switching behavior in such N-polar ScAlN/GaN heterostructures has high uniformity, which is beneficial for further scalable integration and mass production. Meanwhile, remnant polarization retention tests were implemented to reveal the stability of N-polar ScAlN/GaN ferroelectric layers after electrical poling, and to rule out the effect of defects and traps induced charging and discharging processes on evaluation of the displacement current. FIG. 17, part (b), displays the remnant polarization of Sc_{0.21}Al_{0.79}N versus retention time. The remnant polarization in both directions (+Pᵣ and −Pᵣ) shows negligible degradation over 10⁵ seconds, suggesting little polarization loss with time, thereby also excluding the charging effect from defects and/or traps.

Endurance testing was performed on the example N-polar Sc_{0.21}Al_{0.79}N films under repetitive bipolar cycling. As shown in FIG. 17, part (c), the remnant polarization in both directions did not exhibit obvious fatigue behavior over 5×10⁵ switching cycles. Then the remnant polarization gradually decreases with further increasing switching cycles. Finally, the ferroelectric behavior becomes paraelectric, which is similar to the fatigue behavior of single-crystalline ferroelectric M-polar ScAlN, but is different from the dielectric breakdown behavior observed in sputtering deposited ScAlN films during cycling. In spite of the limited quality of the N-polar GaN template, the endurance cycle limit here is comparable to that of M-polar ScAlN and is in fact among the highest values reported. The variation of coercive field recorded after selected switching cycles is plotted in FIG. 17, part (d). Coercive fields in both branches show stability in the measured 10⁵ switching cycles with standard deviations less than 0.1 MV/cm, establishing a promising working platform for epitaxial ferroelectric ScAlN based electronic devices.

The ferroelectric switching behavior in N-polar Sc_{0.16}Al_{0.84}N, Sc_{0.29}Al_{0.71}N, and Sc_{0.36}Al_{0.64}N films has been also studied using the above characterization methods. Clear displacement current peaks induced by polarized charge transfer process have been observed in both N-polar Sc_{0.16}Al_{0.84}N and Sc_{0.29}Al_{0.71}N films, suggesting those ScAlN films are ferroelectrics as well. The average coercive field was measured at 10 kHz is about 5.3 MV/cm and about 3.8 MV/cm for Sc_{0.16}Al_{0.84}N and Sc_{0.29}Al_{0.71}N films, respectively. The Sc_{0.36}Al_{0.64}N film exhibited a relatively large leakage current, and dielectric breakdown happened before ferroelectric switching. For N-polar ScAlN films with lower Sc content (e.g., less than 0.3), the evolution of both coercive field and remnant polarization shows a similar trend to the M-polar ScAlN/GaN heterostructures.

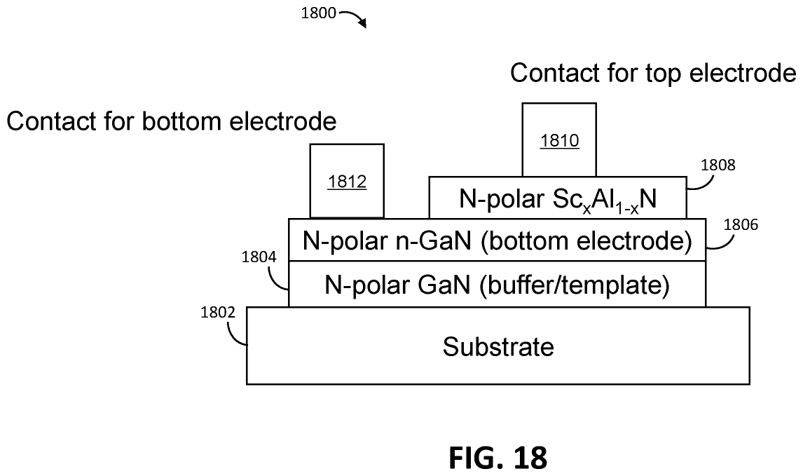

FIG. 18 shows a heterostructure device 1800 having a ferroelectric heterostructure in accordance with one example. In this case, the device 1800 is configured as a capacitor. Other types of devices may be realized. For instance, the heterostructure device 1800 may include any number of additional or alternative layers, components, or other elements to realize other device configurations.

The device 1800 includes a substrate 1802 and a heterostructure supported by the substrate. The substrate 1802 may be composed of, or otherwise include, sapphire or silicon. Other substrate materials may be used, as described herein.

In the example of FIG. 18, the heterostructure includes a semiconductor buffer or template layer 1804 supported by the substrate 1802. The semiconductor material of the buffer or template layer 1804 is N-polar. In this example, the buffer or template layer 1804 is composed of, or otherwise includes, GaN, but other materials may be used, as described herein. In some cases (e.g., sapphire substrate cases), the heterostructure may not include a buffer layer. In still other cases, the heterostructure may include multiple semiconductor layers, e.g., one or more buffer layers and one or more template layers.

The heterostructure includes a bottom or lower electrode layer 1806. The electrode layer 1806 may be a doped semiconductor layer. In this example, the bottom electrode layer 1806 is composed of, or otherwise includes, silicon-doped (n-type) GaN, but other materials may be used, as described herein. In this case, the polarity of the bottom electrode layer 1806 is established by the buffer layer 1804. The bottom electrode layer 1806 is thus also N-polar.

The heterostructure includes a ferroelectric III-nitride alloy layer 1808 supported by the bottom electrode layer 1806 or other semiconductor layer of the heterostructure. As described herein, the ferroelectric III-nitride alloy layer 1808 includes a Group IIIB element. In this example, the ferroelectric III-nitride alloy layer 1808 is composed of, or otherwise includes, ScAlN, but other materials may be used, as described herein. The ferroelectric III-nitride alloy layer 1808 is in contact with the underlying semiconductor layer (e.g., the bottom electrode layer 1806) to establish a heterointerface. In other devices, the layer underlying the ferroelectric layer is undoped.

As described herein, the ferroelectric III-nitride alloy layer 1808 may be monocrystalline, with a wurtzite structure. Any number of the layers of the heterostructure may be nitrogen-polar. In some cases, each of the layers of heterostructure 1804, 1806, 1808 is nitrogen-polar.

The device 1800 may include a number of other structures or components. In the capacitor example of FIG. 18, the device 1800 includes a top contact 1810 for the electrode established by the ferroelectric III-nitride alloy layer 1808 and a bottom contact 1812 for the bottom electrode layer 1806.

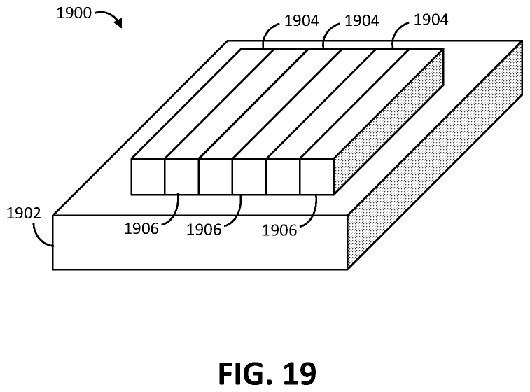

FIG. 19 depicts a device 1900 with a ferroelectric structure (e.g., heterostructure) having an alternating metal polar and N-polar ferroelectric arrangement in accordance with one example. The device 1900 includes a substrate 1902 and one or more ferroelectric layers supported by the substrate 1902. In this example, the alternating arrangement is periodic and provided in a single ferroelectric layer. The arrangement may vary in other cases (e.g., multiple stacked layers, non-periodic positioning, etc.).

The substrate 1902 may be composed of, or otherwise include, sapphire. Additional or alternative materials may be used, as described herein. In some cases, the substrate 1902 is patterned or otherwise formed or configured to promote the alternating arrangement in the ferroelectric layer. Thus, the surface of the substrate 1902 may be configured to establish the polarity of the layer(s) grown thereon. For instance, the substrate 1902 (or the heterostructure supported thereby) may include N-polar AlN regions and metal-polar AlN regions to promote the growth of N-polar and metal-polar regions, respectively, in the ferroelectric layer. Alternative or additional materials may be used to promote different polarity growth, including, for instance, GaN.

The ferroelectric structure of the device 1900 includes N-polar regions 1904 and metal-polar regions 1906. Each region 1904, 1906 is composed of, or otherwise includes, a layer of an alloy of a III-nitride material (e.g., ScₓAl₁₋ₓN). For ease in illustration, only the ScAlN layer is depicted in FIG. 19. The ferroelectric structure may include any number of additional layers, such as buffer or other heterostructure layers (e.g., GaN buffer layers), as described herein. Such additional layers may be disposed between the layer shown and the substrate 1902.

In some cases, the device 1900 includes a set of electrodes (e.g., metal electrodes) disposed in an arrangement along the ferroelectric structure to pole (e.g., periodically pole) the structure. The electrodes are selectively disposed along one or more of the regions 1904, 1906 for separate poling thereof. For instance, in one example, each one of the regions 1906 has a respective electrode in contact therewith. An alternating or other arrangement may thus be realized by applying the appropriate voltages to the electrodes. In other cases, the polarity of each region 1904, 1906 is selectively switched in this manner via respective electrodes on each region 1904, 1906.

The device 1900 may be integrated or otherwise incorporated into a wide variety of devices or systems. For instance, the alternating arrangement of the device 1900 may be useful in connection with non-linear photonic devices and second harmonic generation.

Described above are examples of devices exhibiting robust ferroelectricity in single-crystalline wurtzite phase N-polar ScAlN/GaN heterostructures. The heterostructures were grown on on-axis c-plane sapphire substrates by molecular beam epitaxy. The nearly lattice-matched N-polar Sc_{0.21}Al_{0.79}N/GaN heterostructure exhibited highly uniform coercive filed (about 4.6 MV/cm at 10 kHz) and remnant polarization (about 90 μC/cm²) across the entire wafer. The exactly aligned orientation, both out-of-plane and in-plane, between ScAlN epilayer, GaN, and the underlying sapphire substrate was confirmed using x-ray diffraction (XRD) measurements. The reliability of the N-polar Sc_{0.21}Al_{0.79}N/GaN ferroelectricity was systemically characterized using retention and endurance tests. Both the coercive field and remnant polarization exhibited negligible degradation over 10⁵ switching cycles, which is among the best reported for ferroelectric III-nitrides. The examples provide for fully epitaxial heterogeneous integration of ferroelectricity into N-polar III-nitride heterostructures, which, together with fully epitaxial ferroelectric metal-polar ScAlN, are useful in high-power and high-frequency electronic devices, memory electronic devices, acoustic resonators and filters, optoelectronic devices, integrated quantum photonic devices, and other devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A method of fabricating a heterostructure, the method comprising:
providing a substrate; and
implementing a non-sputtered, epitaxial growth procedure at a growth temperature to form a wurtzite structure supported by the substrate, the wurtzite structure comprising an alloy of a III-nitride material, the non-sputtered, epitaxial growth procedure being configured to incorporate a group IIIB element into the alloy of the III-nitride material;
wherein the growth temperature is at a level such that the wurtzite structure exhibits a breakdown field strength greater than a ferroelectric coercive field strength of the wurtzite structure.

2. The method of claim 1, wherein the level of the growth temperature is at about 650 degrees Celsius or less.

3. The method of claim 1, further comprising forming a semiconductor layer supported by the substrate before implementing the non-sputtered, epitaxial growth procedure such that the wurtzite structure is formed on the semiconductor layer.

4. The method of claim 3, wherein forming the semiconductor layer comprises forming a III-nitride layer.

5. The method of claim 4, wherein the III-nitride layer is nitrogen-polar such that the wurtzite structure is nitrogen-polar.

6. The method of claim 3, wherein the semiconductor layer comprises gallium nitride (GaN).

7. The method of claim 3, wherein forming the semiconductor layer comprises growing the semiconductor layer in an epitaxial growth chamber in which the non-sputtered, epitaxial growth procedure for the wurtzite structure is implemented such that the substrate is not removed from the epitaxial growth chamber between forming the semiconductor layer and implementing the non-sputtered, epitaxial growth procedure.

8. The method of claim 3, wherein the III-nitride layer is configured to promote growth of a metal-polar region, a nitrogen-polar region, or both metal- and nitrogen-polar regions when implementing the non-sputtered, epitaxial growth procedure.

9. The method of claim 1, further comprising forming a semiconductor layer after implementing the non-sputtered, epitaxial growth procedure such that the semiconductor layer is in contact with the wurtzite structure.

10. The method of claim 9, wherein forming the semiconductor layer comprises growing the semiconductor layer in an epitaxial growth chamber in which the non-sputtered, epitaxial growth procedure for the wurtzite structure is implemented such that the substrate is not removed from the epitaxial growth chamber between implementing the non-sputtered, epitaxial growth procedure and forming the semiconductor layer.

11. The method of claim 1, wherein the group IIIB element is scandium.

12. The method of claim 1, wherein the III-nitride material is aluminum nitride (AlN).

13. The method of claim 1, wherein the substrate comprises sapphire.

14. The method of claim 1, wherein the substrate comprises off-cut sapphire.

15. The method of claim 1, further comprising annealing the wurtzite structure at a temperature higher than the growth temperature.

16. The method of claim 15, wherein annealing the wurtzite structure is implemented in a chamber in which the non-sputtered, epitaxial growth procedure is implemented.

17. A method of fabricating a heterostructure, the method comprising:
providing a substrate; and
implementing a non-sputtered, epitaxial growth procedure at a growth temperature to form a wurtzite structure supported by the substrate, the wurtzite structure comprising an alloy of a III-nitride material, the non-sputtered, epitaxial growth procedure being configured to incorporate a Group IIIB element into the alloy of the III-nitride material;
wherein the growth temperature is about 650 degrees Celsius or less.

18. The method of claim 17, further comprising forming a semiconductor layer supported by the substrate before implementing the non-sputtered, epitaxial growth procedure such that the wurtzite structure is formed on the semiconductor layer.

19. The method of claim 18, wherein forming the semiconductor layer comprises forming a III-nitride layer.

20. The method of claim 19, wherein the III-nitride layer is nitrogen-polar such that the wurtzite structure is nitrogen-polar.

21. The method of claim 18, wherein forming the semiconductor layer comprises growing the semiconductor layer in an epitaxial growth chamber in which the non-sputtered, epitaxial growth procedure for the wurtzite structure is implemented such that the substrate is not removed from the epitaxial growth chamber between forming the semiconductor layer and implementing the non-sputtered, epitaxial growth procedure.

22. The method of claim 17, further comprising forming a semiconductor layer after implementing the non-sputtered, epitaxial growth procedure such that the semiconductor layer is in contact with the wurtzite structure.

23. The method of claim 22, wherein forming the semiconductor layer comprises growing the semiconductor layer in an epitaxial growth chamber in which the epitaxial growth procedure for the wurtzite structure is implemented such that the substrate is not removed from the epitaxial growth chamber between implementing the epitaxial growth procedure and forming the semiconductor layer.

24. A device comprising:
a substrate; and
a heterostructure supported by the substrate;
wherein the heterostructure comprises a monocrystalline layer of an alloy of a III-nitride material, and
wherein the alloy comprises a Group IIIB element.

25. The device of claim 24, wherein the monocrystalline layer exhibits a breakdown field strength greater than a ferroelectric coercive field strength of the monocrystalline layer.

26. The device of claim 24, further comprising a semiconductor layer disposed between the substrate and the heterostructure, wherein:
the semiconductor layer comprises a further III-nitride material; and
the semiconductor layer is in contact with the heterostructure.

27. The device of claim 24, further comprising a metal layer disposed between the substrate and the heterostructure, wherein the metal layer is in contact with the heterostructure.

28. A device comprising:
a substrate; and
a heterostructure supported by the substrate;
wherein the heterostructure comprises:
a semiconductor layer supported by the substrate; and
a ferroelectric III-nitride alloy layer supported by the semiconductor layer, the ferroelectric III-nitride alloy layer comprising a Group IIIB element.

29. The device of claim 28, wherein the ferroelectric III-nitride alloy layer is in contact with the semiconductor layer to establish a heterointerface.

30. The device of claim 28, wherein the ferroelectric III-nitride alloy layer is monocrystalline.

31. The device of claim 28, wherein the ferroelectric III-nitride alloy layer has a wurtzite structure.

32. The device of claim 28, wherein the semiconductor layer comprises Si-doped GaN.

33. The device of claim 28, wherein the semiconductor layer is in contact with the substrate.

34. The device of claim 28, wherein the ferroelectric III-nitride alloy layer comprises ScAlN.

35. The device of claim 28, wherein:
the semiconductor layer comprises a III-nitride semiconductor;
the semiconductor layer is nitrogen-polar; and
the ferroelectric III-nitride alloy layer is nitrogen-polar.
